(19) United States
(12) Patent Application Publication
(10) Pub. No.: US 2023/0038411 A1
(43) Pub. Date: Feb. 9, 2023

(54) SEMICONDUCTOR PACKAGE WITH RAISED DAM ON CLIP OR LEADFRAME

(71) Applicant: Texas Instruments Incorporated, Dallas, TX (US)

(72) Inventor: Makoto Shibuya, Beppu City (JP)

(73) Assignee: Texas Instruments Incorporated, (omitted)

(21) Appl. No.: 17/392,738

(22) Filed: Aug. 3, 2021

(51) Int. Cl. H01L 23/31; H01L 23/495; H01L 23/00; H01L 23/10; H01L 21/56

(52) U.S. Cl. CPC H01L 23/3107; H01L 21/56; H01L 23/10; H01L 23/49503; H01L 24/48; H01L 2224/48175

(57) ABSTRACT

A semiconductor package includes a semiconductor die including circuitry electrically coupled to bond pads that is mounted onto a leadframe. The leadframe includes a plurality of leads and a dam bar having a transverse portion that extends between adjoining ones of the leads. The bond pads are electrically connected to the plurality of leads. A raised dam pattern is on the dam bar or on an edge of an exposed portion of a top side clip of the semiconductor package that is positioned above and connects to the semiconductor die. The raised dam pattern includes a first material that is different relative to the material of the dam bar or the clip. A mold material encapsulates the semiconductor die.

### FIELD

This Disclosure relates to semiconductor packages, or more specifically to mold flash prevention for leadframes and clips of semiconductor packages.

### BACKGROUND

Semiconductor die are conventionally first attached to a die pad (also called a support pad) of the leadframe. Bond pads are connected to nodes in the circuitry of the semiconductor die, which can then be individually attached by wire bonding to corresponding contact pads on the ends of the leads. In another arrangement termed a flipchip package, the semiconductor die is flipchip attached to the leadframe.

After the wire bonding or the flipchip assembly operation is completed, the leadframe generally in the form of a leadframe sheet (also known as a leadframe panel) including a plurality of leadframes is placed in a mold apparatus. The mold apparatus is provided with a reservoir having a quantity of an electrically insulating, molding material that generally comprises an epoxy material. During the molding step the molding material is injected into the mold in order to encapsulate the semiconductor die.

In case of semiconductor packages having a die pad, the die pads are each themselves supported by at least two parallel siderails. In some arrangements the die pad is supported on all four sides (right, left, top and bottom) by respective siderails. Each of the siderails is located in the plane of the leadframe and on opposite sides of the die pad, and there is a tie bar between the die pad and the respective siderails.

In the molding operation, a mold cavity is formed around the respective leadframes of the leadframe sheet intended to tightly close and seal upon themselves as well as around a metal comprising dam bar that is an integral part of the leadframe. The dam bar includes a transverse portion that extends between pairs of adjoining leads. The dam bar is intended to restrict the flow of the mold material during molding from bleeding out from the mold cavity enclosed leadframe. After encapsulation, the dam bar and the portion between adjoining leads is typically removed by a punch apparatus. The punch apparatus can comprise a typical metal punch that readily severs the dam bar.

Mold flash occurs when a thin layer of mold material is forced out of the mold cavity (thus beyond the mold outline) onto outer/exposed portion the leads adjacent to the mold outline. This excess mold material on the lead portions beyond the mold outline material is conventionally removed by a process that is commonly termed deflashing. During the dam bar cutting process, such as using a punch apparatus, the adjacent leads are electrically isolated from one another, where the mold flash can break and tend to leave behind some loose mold material. The loose mold flash material that drops during the dam bar cut and trim/form processes can find its way onto the outer lead portions of the leads and as a result cause quality and package yield reduction issues such as a dented leads, lead contamination (embedded with loose mold flash) and bent leads. Sometimes the mold flash material remains on the leads even after a deflash process.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects recognize a cost-effective way to help prevent mold flash is needed, such as in the case of a small outline transistor (SOT) package, or a small outline package (SOP) each being examples of the highest unit density leadframe strip (or leadframe panel) design semiconductor packages. Increasing the unit density on a leadframe strip for cost reduction as noted above is recognized to result in a higher unit density design and a decrease in the needed mold clamp force per unit. A lower magnitude mold clamp force however increases the risk of mold flash, and the maximum clamp force is generally limited by specifications of the molding apparatus.

Even using a relatively high clamp force molding process, such as over 40 kgs/mm² of clamp force, mold flash occurring during the molding process generally still takes place. It is recognized herein that mold flash occurs because the leadframe surface generally has a microstructure that results in the metal (typically comprising copper) of the leadframe having micron level surface roughness, so that during the molding process, the low viscosity (heated) mold material can bleed out past the mold outline and then beyond the dam bar by following pathways within the microstructure. For example, a roughened copper leadframe generally experiences more mold flash as compared to a relatively smooth copper leadframe.

Disclosed aspects include a semiconductor package including a leadframe, the semiconductor package comprising a disclosed raised dam pattern and a semiconductor die comprising circuitry electrically coupled to bond pads that is mounted onto the leadframe. The leadframe can be a leadless leadframe or a leaded leadframe. The leadframe includes a plurality of leads and a dam bar having a transverse portion that extends between adjoining leads. The bond pads are electrically connected to the leads. The raised dam pattern is on the dam bar or in the case the semiconductor package includes a top side clip is on an exposed portion of a top side clip, where the top side clip is positioned above and connects to bond pads on the semiconductor die. The raised dam pattern includes a first material that is different relative to the material of the dam bar or of the clip. A mold material encapsulates the semiconductor die.

### BRIEF DESCRIPTION OF THE DRAWINGS

Reference will now be made to the accompanying drawings, which are not necessarily drawn to scale, wherein:

FIG. 1A is a cross-sectional view that depicts a portion of a leadframe showing a dam bar between an outer lead portion and inner lead portion of a lead just before the top plate and the bottom plate of a molding apparatus contacts on opposing sides of the dam bar. FIG. 1B is a cross-sectional view that depicts the result after molding using the molding apparatus to form a mold material, where mold flash is shown under the top plate, under the bottom plate, on the dam bar and on the outer lead portion. FIG. 1C is a top view depiction looking through the mold material above corresponding to the structure shown in FIG. 1B with the view showing three adjacent leads again showing the mold flash.

FIG. 1D is a cross-sectional view that depicts a portion of a leadframe showing a dam bar between an outer lead portion and inner lead portion of the lead of the leadframe just before the top plate and the bottom plate of a mold apparatus contacts opposing sides of the dam bar, where there is shown a portion of a raised dam pattern on the dam bar. FIG. 1E is a cross-sectional view that depicts the result after molding to form a mold material using the molding apparatus, where due to the presence of the raised dam pattern on the dam bar there is no mold flash shown under the top plate, under the bottom plate, on the dam bar or on the outer lead portion. FIG. 1F is a top view depiction looking through the mold material above corresponding to the structure shown in FIG. 1E with the view showing three adjacent leads shown as 121, 122, 123 each showing the absence of the mold flash that is shown in FIGS. 1B and 1C.

FIGS. 2A and 2B are both regarding a disclosed raised dam pattern on a high unit density leadframe strip design that enables the mold injection using appropriately configured mold plates to cover an entire vertical row of the leadframe sheet, where injection is one row at a time.

FIG. 2A is a top view depiction of a portion of an example leadframe sheet including a plurality of leadframes shown comprising 9 leadframes, including a raised dam pattern now shown on the dam bar provided for each leadframe, before molding. Each leadframe includes a die pad and the tie bars shown. The raised dam pattern is shown as parallel lines each on the dam bar, where the lines run a length of the leadframe sheet in one direction shown as being oriented down to up in FIG. 2A. The raised dam pattern can be configured as a plurality of parallel lines for this high unit density leadframe strip design because mold flash is not a problem perpendicular to the parallel lines at the top and the bottom of each package. FIG. 2B shows the leadframe sheet shown in FIG. 2A after molding to form a mold material. It can be seen in FIG. 2B that the raised dam pattern prevented mold flash from extending beyond the mold outline (the edge of the mold material).

FIG. 2C is a top view depiction of a conventional leadframe having a disclosed raised dam pattern shown as a ring. Unlike the raised dam pattern comprising a plurality of parallel lines for a high unit density leadframe strip design, a disclosed raised dam pattern for this conventional leadframe design would be placed to cover an entire perimeter around each individual leadframe unit. The mold material is only shown with its outer boundary that being the mold outline. It can be seen that the raised dam pattern is positioned beyond the mold outline and is on both the dam bar and the top and bottom rails to form a rectangular-shaped ring.

FIG. 3A is a cross-sectional view of an example semiconductor package shown as a wirebonded package including a semiconductor die, where the leadframe includes a disclosed raised dam on the outer lead portion of the leads, according to an example aspect.

FIG. 3B is a cross-sectional view of an example semiconductor package, shown as a flipchip on lead (FCOL) package having a disclosed raised dam pattern shown on the outer lead portions of the leads.

FIGS. 4A-4C depict successive views relating to the molding step of an in-process semiconductor package, according to an example aspect. In FIG. 4A a leadframe sheet is shown comprising a plurality of leadframes. In FIG. 4B, the in-process semiconductor package is shown after printing or otherwise forming a raised dam pattern on the dam bars. The raised dam pattern in FIG. 4B is shown as a series of parallel lines due to use of an optional bar-shaped mold as described above that provides higher unit density. FIG. 4C shows the in-process semiconductor package resulting after molding to form a mold material, where the raised dam pattern prevents mold flash.

FIGS. 5A and 5B show an in-process clip quad flat no-lead (QFN) package having a top semiconductor die and a bottom semiconductor die, and a top clip and a bottom clip, with enhanced top side cooling enabled by an exposed portion of the top clip bounded by disclosed raised dam pattern on the top side of the clip QFN package. FIG. 5A shows the in-process clip QFN package after a first molding process that does not mold over the top clip, while FIG. 5B shows the in-process clip QFN package after forming a raised dam pattern on the top clip, and then a second molding process to form additional mold material on the top clip, where the raised dam pattern prevents mold flash enabling a portion of the top clip to be exposed to the environment as shown.

FIG. 5C shows a top view and FIG. 5D a perspective view of a gang clip including a plurality of clips, including a disclosed raised dam pattern shown configured as a ring on the clips. The raised dam pattern position corresponds to roughly an outer area of the top semiconductor die.

FIG. 6 is a flowchart that shows steps for an example method of assembling a disclosed semiconductor package.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this Disclosure.

Also, the terms "connected to" or "connected with" (and the like) as used herein without further qualification are intended to describe either an indirect or direct electrical connection. Thus, if a first device "connects" to a second device, that connection can be through a direct electrical connection where there are only parasitics in the pathway, or through an indirect electrical connection via intervening items including other devices and connections. For indirect connecting, the intervening item generally does not modify the information of a signal but may adjust its current level, voltage level, and/or power level.

Upon formation, a disclosed raised dam pattern is generally an enclosed pattern that may be referred to being a ring. Besides a dielectric material such as solder resist (SR), an electrically conductive material can also be used for forming the raised dam pattern. SR is also sometimes called solder mask, or solder stop mask, is known to be a thin lacquer-like layer of polymer that is commonly applied to the copper traces of a printed circuit board (PCB) for protection against oxidation, and to prevent solder bridges from forming between closely spaced solder pads.

It is recognized that the height (or thickness) of the mold flash is typically less than about 10 µm. Therefore, a disclosed raised dam pattern height of 20 to 30 µm (being greater than the height of the mold flash) is generally effective to prevent mold flash, where the mold material that would otherwise become mold flash by bleeding out onto the outer lead portion of the leads, or onto the exposed portion of a top clip in the case of a semiconductor package having a top side clip designed to be partially exposed for added cooling, is prevented. The raised dam pattern functions to stop mold flash, by acting as a mold restraining dam during the molding process. Without a disclosed raised dam pattern, mold flash is recognized to generally be caused by not enough mold clamp pressure being applied due to a high unit density or a larger size leadframe size so that there is not enough clamp force area, particularly in the case of significant microstructure (resulting in surface roughness) on the leadframe or clip surface.

A disclosed aspect is to form (e.g., using an inkjet printing process) a raised dam pattern, such as comprising SR, or another relatively low modulus material such as an epoxy or an acrylic, on the dam bar in the case of a leadframe to form what is referred to herein as a raised dam pattern. A raised dam bar pattern in the case of a leadframe is formed on the dam bar, and in the case of a semiconductor package including an exposed (from the mold material) top side clip the raised dam pattern is formed on the edge of the top side clip of the package, where the exposed top clip portion improves the top side heat dissipation for the semiconductor package.

The height of a disclosed raised dam pattern can be controlled in the case of inkjet printing by the inkjet printing pattern. Usually, the inkjet printing parameters for controlling the height of the raised dam pattern is obtained by setting one or more of the following inkjet printing parameters comprising the droplet size, number of printed layers, and the resolution of the target pattern which is generally expressed as dots per inch (dpi). The raised dam pattern on a completed standalone semiconductor package in the case of a leadframe is generally no longer an enclosed pattern (ring) or a line because the raised dam pattern is only on the outer lead portion, where after molding and coining singulation there is a cutting of a portion of the dam bar pattern between the leads.

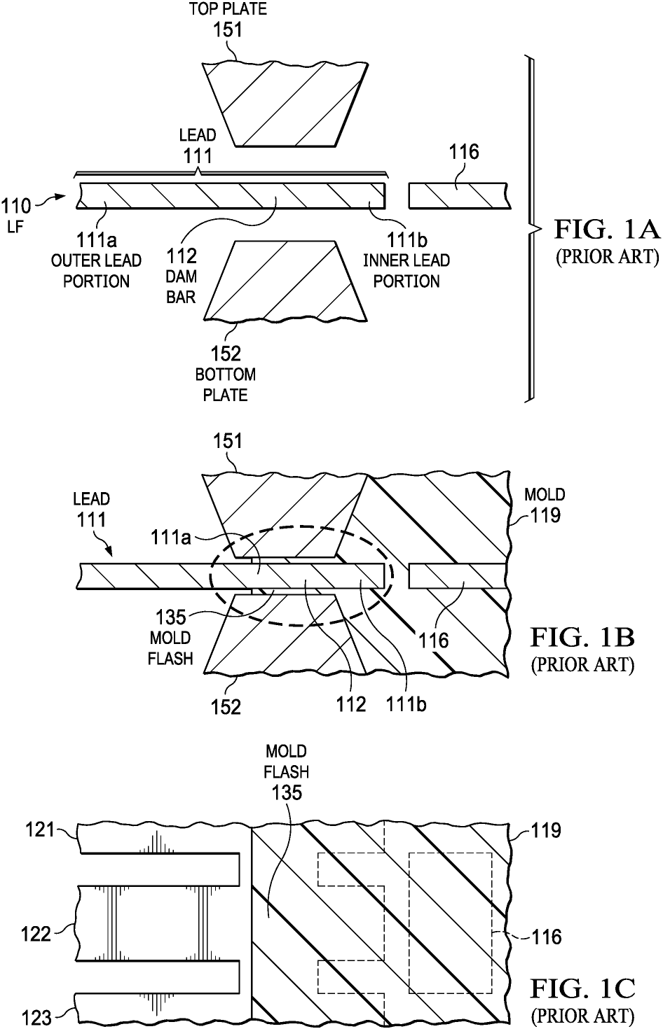

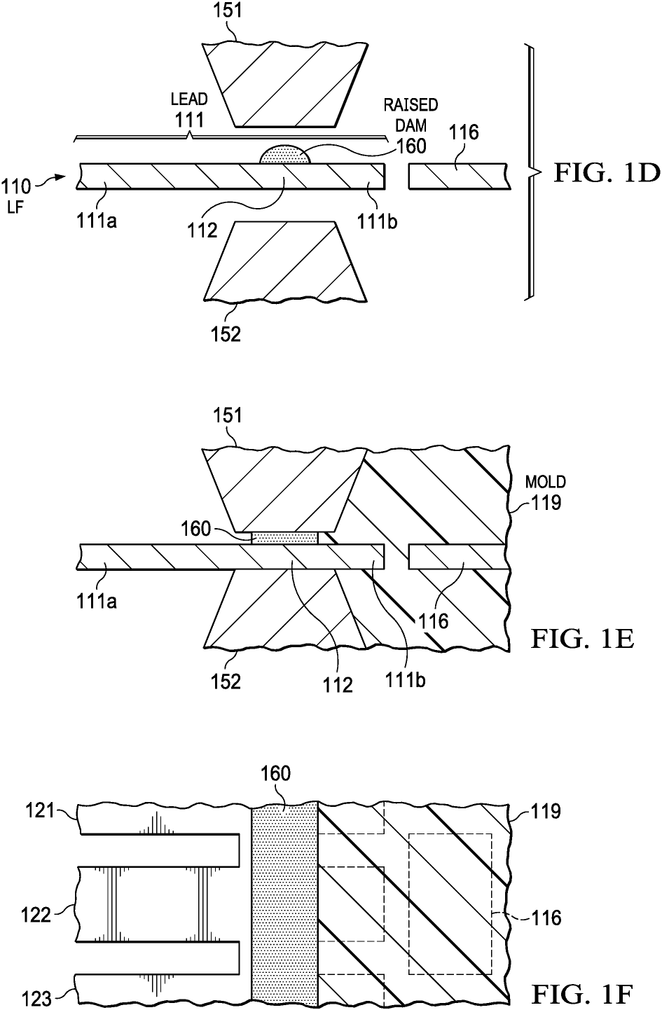

FIG. 1A is a cross-sectional view that depicts a portion of a leadframe 110 showing a dam bar 112 between an outer lead portion 111a and inner lead portion 111b of a lead 111 just before the top plate 151 and the bottom plate 152 of a mold apparatus contacts on opposing sides of the dam bar 112. A die pad 116 is also shown.

FIG. 1B is a cross-sectional view that depicts the result after molding using the molding apparatus to form a mold material 119, where mold flash 135 is shown under the top plate 151, under the bottom plate 152, on the dam bar 112, and on the outer lead portion 111a. FIG. 1C is a top view depiction corresponding to the structure shown in FIG. 1B with the top side of the mold compound transparent and expanded to show three leads 121, 122 and 123, again showing mold flash 135 on the outer lead portion of the leads.

FIG. 1D is a cross-sectional view that depicts a portion of a leadframe 110 showing a dam bar 112 between an outer lead portion 111a and an inner lead portion 111b of the lead 111 just before the top plate 151 and the bottom plate 152 of a mold apparatus contacts opposing sides of the dam bar 112, where there is shown a portion of a disclosed raised dam pattern 160 on the dam bar 112. FIG. 1E is a cross-sectional view that depicts the result after molding to form a mold material 119 using the molding apparatus, where due to the presence of the raised dam pattern 160 there is no mold flash shown under the top plate 151, under the bottom plate 152, on the dam bar 112, or on the outer lead portion 111a. FIG. 1F is a top view depiction corresponding to the structure shown in FIG. 1E with the view showing three leads shown as 121, 122, and 123, each showing the absence of any mold flash 135 that as described above is shown in FIGS. 1B and 1C.

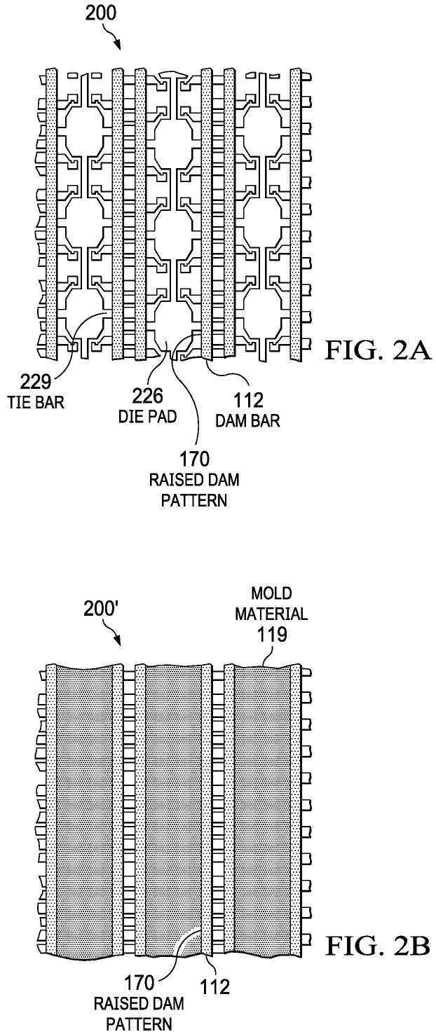

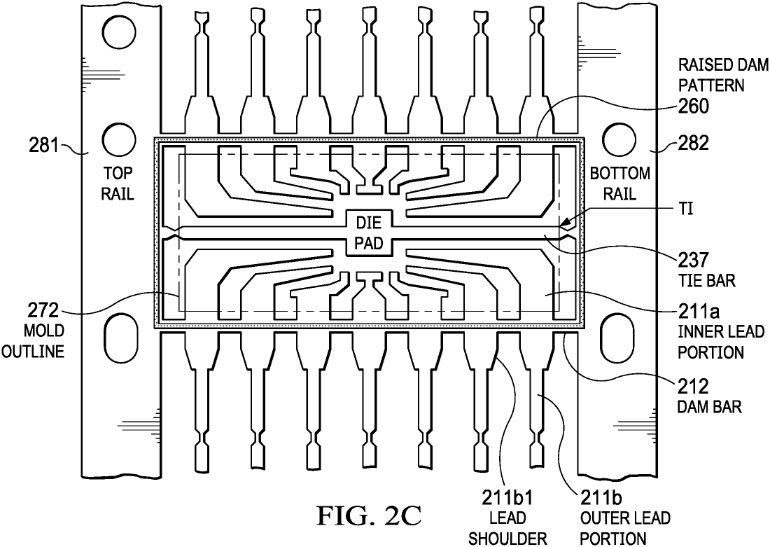

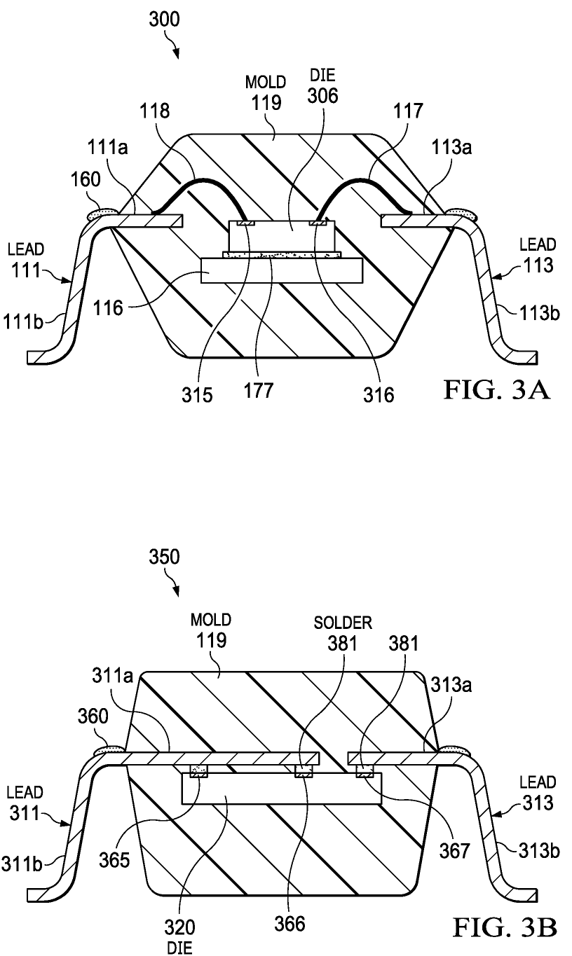

FIG. 2A is a top view depiction of a portion of an example leadframe sheet 200 including a plurality of leadframes shown comprising 9 leadframes, including a raised dam pattern 170 shown on the dam bar 112 provided for each leadframe, before molding. Each leadframe includes a die pad 226 and the tie bars 229 shown. The raised dam pattern 170 is shown as parallel lines on the dam bars 112, where the lines run a length of the leadframe sheet in one direction shown as being down to up in FIG. 2A. This connected unit mold design of the leadframe sheet 200 provides higher unit density because the mold cavity is not for individual leadframe units, but is instead "common", so that the dam-bar pattern 170 is not ring shaped, rather is configured as continuous parallel lines.

FIG. 2B shows the leadframe sheet 200 shown in FIG. 2A after molding now shown as 200' now including a mold material 119. It can be seen in FIG. 2B that the raised dam pattern 170 prevented mold flash of the mold material 119 extending beyond the mold outline (the edge of the mold material).

FIG. 2C is a top view depiction of a conventional leadframe having a disclosed raised dam pattern 260 shown as a ring. It can be seen that the raised dam pattern 260 is beyond the mold outline 272 on both the dam bar 212 and the top and bottom rails 281, 282 to form a rectangular ring. Identified for the leads is an inner lead portion 211a that is within the mold outline 272, and an outer lead portion 211b including a lead shoulder 211b₁ that is outside the mold outline 272.

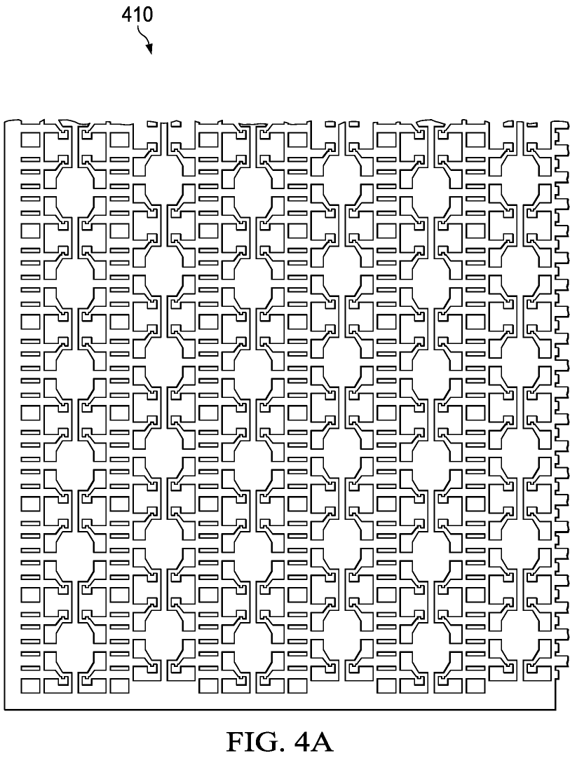

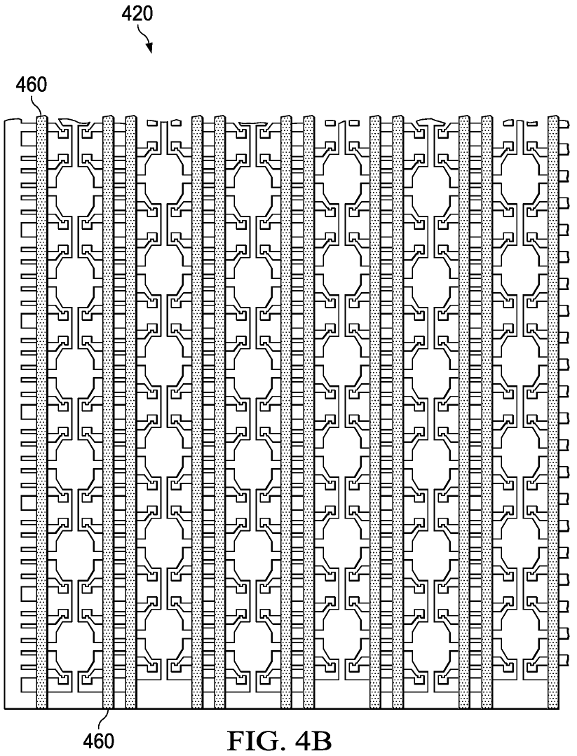

FIG. 3A is a cross-sectional view of a semiconductor package 300 shown as a wirebonded package including a semiconductor die 306, where the leadframe includes a disclosed raised dam pattern 160 on the outer lead portion 111b and 113b of the leads 111 and 113, according to an example aspect. The semiconductor die 306 includes at least a semiconductor surface and generally comprises an integrated circuit (IC). The inner lead portions are shown as 111a and 113a. The raised dam pattern 160 is outside of the mold material 119 because it is on the dam bar 160. Die attachment material for attaching the semiconductor die 306 to the die pad 116 is shown as 177, and bond pads coupled to circuitry of the semiconductor die are shown as 315 and 316. There is a wirebond 118 from the bond pad 315 to the inner lead portion 111a, and a wire bond 117 from the bond pad 316 to the inner lead portion 113a.

The circuitry on the semiconductor die 306 comprises circuit elements (including transistors, and generally diodes, resistors, capacitors, etc.) which may optionally be formed in an epitaxial layer on a bulk substrate material such as silicon that is configured together for generally realizing at least one circuit function. Example circuit functions include analog (e.g., amplifier or power converter), radio frequency (RF), digital, or non-volatile memory functions.

FIG. 3B is a cross-sectional view of a semiconductor package 350, shown as a package having a disclosed raised dam pattern 360 shown on the outer lead portions 311b and 313b of leads 311 and 313. The leads 311 and 313 include inner lead portions 311a and 313a. The semiconductor die 320 has bond pads 365, 366, 367, where bond pads 365 and 366 are attached to the inner lead portion 311a by solder 381, and bond pad 367 is shown attached to the inner lead portion 313a by solder 381.

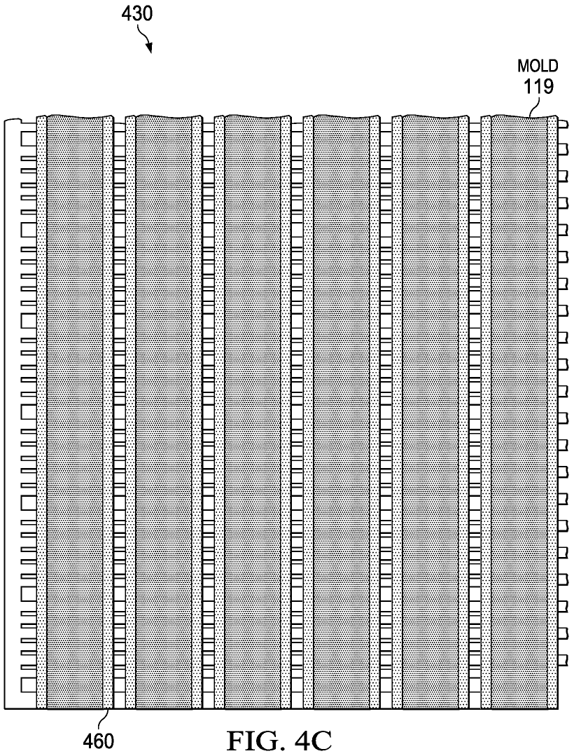

FIGS. 4A-4C depict successive views relating to the molding step of an in-process semiconductor package, according to an example aspect. In FIG. 4A a leadframe sheet is shown as 410 comprising a plurality of interconnected leadframes. In FIG. 4B, the in-process semiconductor package is shown as 420 after printing or otherwise forming a raised dam pattern 460 on the dam bars. The raised dam pattern 460 in FIG. 4B comprises a series of parallel lines due to use of an optional bar shaped mold as described above that provides higher unit density. During the molding process, the raised dam pattern 460 on the dam bar prevents mold flash from reaching the outer lead portions. Further details for the leadframe of the in-process semiconductor package 420 can be found in FIG. 2A described above.

Then, attaching a semiconductor die to each leadframe follows, which in the case of a wirebond package is onto a die pad which is followed by wirebonding. FIG. 4C shows the in-process semiconductor package as 430 resulting after molding to form a mold material 119, where the raised dam pattern 460 prevents mold flash. Further details for the in-process semiconductor package 450 can be found in FIG. 2B described above. Subsequent assembly processing can comprise a trim/form process, while some semiconductor packages may use trim and singulation.

The forming of the raised dam pattern 460 shown in FIGS. 4B and 4C, and more generally for disclosed aspects, can occur before or after the semiconductor die attachment step. However, forming the raised dam pattern 460 before the semiconductor die attachment has the advantage of not risking contamination of the semiconductor die during the process used to form the raised dam pattern 460.

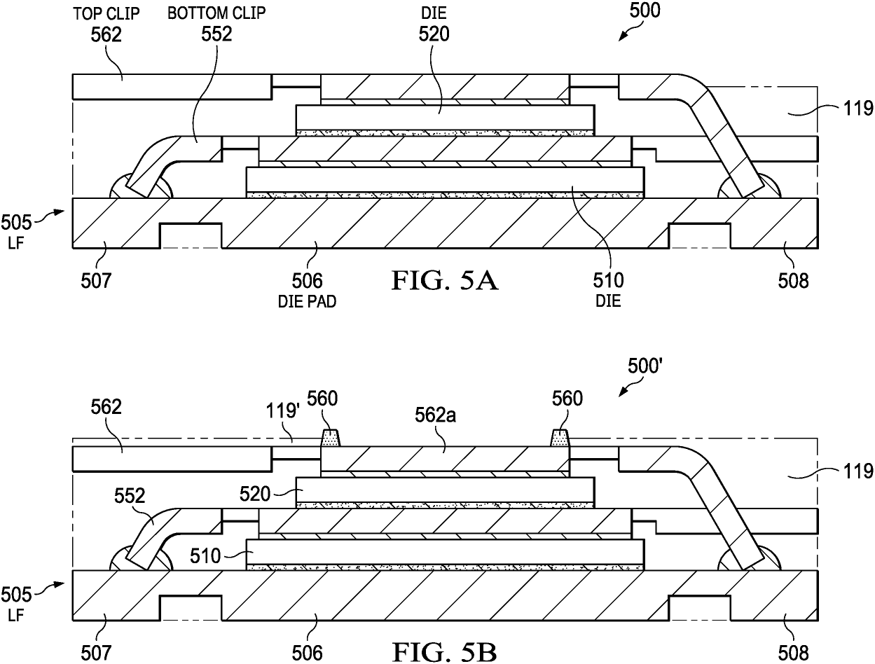

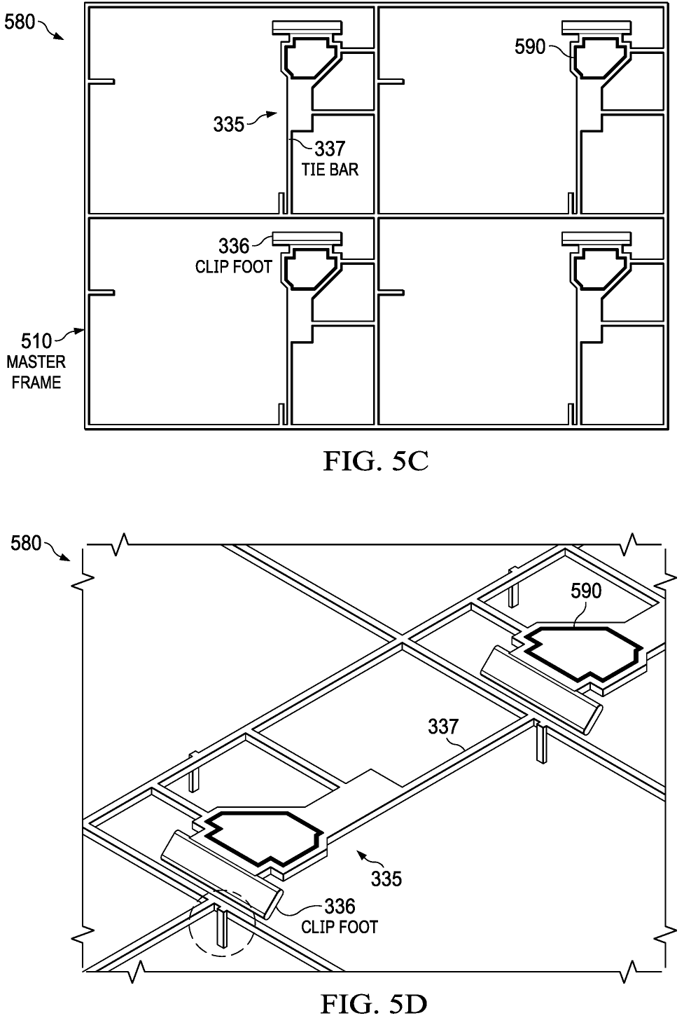

FIGS. 5A and 5B show an in-process clip QFN package 500 and 500' comprising a top semiconductor die 520 and a bottom semiconductor die 510, and a top clip 562 and a bottom clip 552. QFN package 500' provides enhanced top side cooling enabled by an exposed portion of the top clip 562 bounded by a disclosed raised dam pattern 560 on the top side of the QFN package. The mold material is again shown as 119. FIG. 5A shows the in-process QFN package 500 including a leadframe 505 including leads 507 and 508 and a die pad 506 after a first molding process that provides a mold material 119 but does not mold over the top clip 562. FIG. 5B shows the in-process QFN package 500' after forming a raised dam pattern 560 on the top clip 562, and then a second molding process to form additional mold material 119' on the top clip 562, where the raised dam pattern 560 prevents mold flash enabling an inner portion of the top clip 562 shown as 562a to be exposed to the environment. The raised dam pattern 560 corresponds to roughly to the outer area boundary of the top semiconductor die.

FIG. 5C shows a top view and FIG. 5D a perspective view of a gang clip 580 comprising a master frame 540 including a plurality of clips 335 including a clip foot 336, where the clips 335 are secured to the master frame 540 by a| tie bar 337. The raised dam pattern shown as 590 is shown configured as a ring on the clips 335. The clips 335 are suitable for being a top clip having an exposed portion for a top side enhanced semiconductor package, such as shown in FIG. 5B described above.

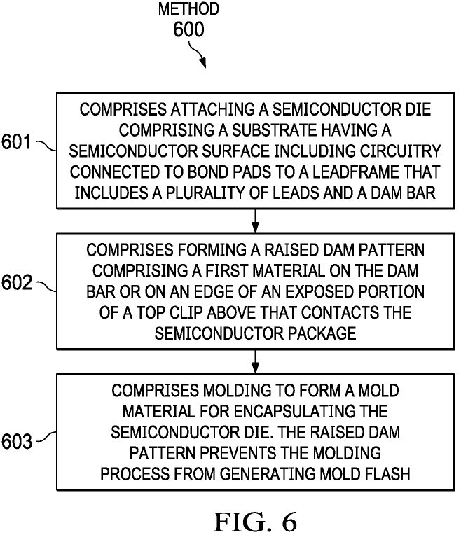

FIG. 6 is a flowchart that shows steps for an example method 600 of assembling a disclosed semiconductor package. Step 601 comprises attaching a semiconductor die comprising a substrate having a semiconductor surface including circuitry connected to bond pads to a leadframe that includes a plurality of leads and a dam bar. Step 602 comprises forming a raised dam pattern comprising a first material on the dam bar or on an edge of an exposed portion of a top clip above that contacts the semiconductor package. Step 603 comprises molding to form a mold material for encapsulating the semiconductor die. The raised dam pattern prevents the molding process from generating mold flash.

As described above the forming of the raised dam pattern can occur before the attaching of the semiconductor die, and the forming of the raised dam pattern can comprise inkjet printing. The molding can be exclusive of a deflash process.

Disclosed aspects can be integrated into a variety of assembly flows to form a variety of different semiconductor packages and related products. The semiconductor package can comprise single IC die or multiple IC die, such as configurations comprising a plurality of stacked IC die, or laterally positioned IC die. A variety of package substrates may be used. The IC die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the IC die can be formed from a variety of processes including bipolar, insulated-gate bipolar transistor (IGBT), CMOS, BiCMOS and MEMS.

Those skilled in the art to which this Disclosure relates will appreciate that many variations of disclosed aspects are possible within the scope of the claimed invention, and further additions, deletions, substitutions and modifications may be made to the above-described aspects without departing from the scope of this Disclosure.

1. A semiconductor package, comprising:
a semiconductor die including circuitry coupled to bond pads mounted onto a leadframe;
the leadframe including a plurality of leads and a dam bar having a transverse portion that extends between adjoining ones of the plurality of leads;
the semiconductor die electrically connected to the plurality of leads;
a raised dam pattern on the dam bar or on an edge of an exposed portion of a top side clip of the semiconductor package that is positioned above and connects to the semiconductor die, the raised dam pattern comprising a first material that is different relative to a material of the dam bar or of the clip; and
a mold material encapsulating the semiconductor die.

2. The semiconductor package of claim 1, wherein the semiconductor package comprises a flipchip package.

3. The semiconductor package of claim 1, wherein the leadframe include a die pad, and wherein there are bondwires between the bond pads and the plurality of leads so that the semiconductor package is a wirebond package.

4. The semiconductor package of claim 1, wherein a height of the raised dam pattern is 10 to 30 µm.

5. The semiconductor package of claim 1, wherein the first material comprises solder resist (SR).

6. The semiconductor package of claim 1, wherein the raised dam pattern defines a rectangular shape.

7. The semiconductor package of claim 1, where the semiconductor package includes the top side clip.

8. The semiconductor package of claim 7, wherein the leadframe comprises a leadless leadframe.

9. The semiconductor package of claim 1, wherein the semiconductor die comprises an integrated circuit (IC).

10. A method of assembling a semiconductor package, comprising:
attaching a semiconductor die comprising a substrate having a semiconductor surface including circuitry connected to bond pads to a leadframe that includes a plurality of leads and a dam bar;
forming a raised dam pattern comprising a first material on the dam bar or on an edge of an exposed portion of a top clip above that contacts of the semiconductor package, and
molding to form a mold material for encapsulating the semiconductor die.

11. The method of claim 10, wherein the forming of the raised dam pattern occurs before the attaching of the semiconductor die.

12. The method of claim 10, wherein the forming of the raised dam pattern comprises inkjet printing.

13. The method of claim 10, wherein the molding is exclusive of a deflash process.

14. The method of claim 10, wherein the leadframe comprises a leadframe sheet including a plurality of the leadframes, further comprising after the molding singulating including cutting the leadframe sheet to form a plurality of the semiconductor packages.

15. The method of claim 10, wherein the first material comprises solder resist (SR).

16. The method of claim 10, wherein a height of the raised dam pattern is 10 µm to 30 µm .

17. The method of claim 10, wherein the semiconductor package includes the top side clip.

18. The method of claim 17, wherein the leadframe comprises a leadless leadframe.

19. The method of claim 10, wherein the semiconductor die comprises an integrated circuit (IC).

20. A semiconductor package, comprising:
a semiconductor die including circuitry coupled to bond pads mounted onto a leadframe;
the leadframe including a plurality of leads and a dam bar having a transverse portion that extends between adjoining ones of the plurality of leads;
the semiconductor die electrically connected to the plurality of leads;
a raised dam pattern on the dam bar comprising a first material that is different relative to a material of the dam bar; and
a mold material encapsulating the semiconductor die.
